(19) United States
(12) Patent Application Publication
(10) Pub. No.: US 2025/0079389 A1
(43) Pub. Date: Mar. 6, 2025

(54) SEMICONDUCTOR DEVICE AND METHOD OF MANUFACTURING THE SAME

(71) Applicant: Renesas Electronics Corporation, Tokyo (JP)

(72) Inventor: Yoshiharu SHIMIZU, Tokyo (JP)

(21) Appl. No.: 18/799,362

(22) Filed: Aug. 9, 2024

(30) Foreign Application Priority Data
Sep. 4, 2023 (JP) 2023-142929

(51) Int. Cl. H01L 23/00; H01L 21/48; H01L 21/56; H01L 23/13; H01L 23/498

(52) U.S. Cl. CPC H01L 24/48; H01L 21/4846; H01L 23/13; H01L 23/49838; H01L 24/04; H01L 24/85; H01L 21/56; H01L 24/32; H01L 24/73; H01L 24/96; H01L 24/97; H01L 2224/04042; H01L 2224/32245; H01L 2224/45; H01L 2224/45144; H01L 2224/45147; H01L 2224/48245; H01L 2224/48453; H01L 2224/48463; H01L 2224/73265; H01L 2224/85205; H01L 2224/96; H01L 2224/97; H01L 2924/1815

(57) ABSTRACT

In plan view, an electrode pad of a semiconductor chip includes: a first region that contains a center of an exposed portion of the electrode pad; a second region that is located around the first region; and a third region that is located around the first region and that is located between the first region and the second region. Here, a first groove that separates a plurality of semiconductor elements formed in a semiconductor substrate from each other is formed in the semiconductor substrate. The semiconductor substrate includes: a fourth region that overlaps with the third region but not overlaps with each of the first region and the second region, and a fifth region that overlaps with the first region but not overlaps with the third region. And, the first groove is formed in the semiconductor substrate at the fifth region but not at the fourth region.

### CROSS-REFERENCE TO RELATED APPLICATIONS

The disclosure of Japanese Patent Application No. 2023-142929 filed on Sep. 4, 2023, including the specification, drawings and abstract is incorporated herein by reference in its entirety.

### BACKGROUND

The present invention relates to a semiconductor device.

Here, there are disclosed techniques listed below.

[Patent Document 1] Japanese Unexamined Patent Application Publication No. 2023-11445

Patent Document 1 discloses a semiconductor device in which a groove is formed on an upper surface of a semiconductor substrate at a position which is overlapping with an electrode pad formed over the upper surface of this semiconductor substrate, and which is spaced apart from the device isolation arrangement prohibited area overlapping with an end portion of a ball portion of a copper wire bonded to the electrode pad.

### SUMMARY

As shown in Patent Document 1, an element isolation trench for separating a plurality of elements from each other is formed in the semiconductor substrate. If the element isolation trench formed on the semiconductor substrate is located at the position overlapping with the electrode pad formed over the upper surface of the semiconductor substrate, around the element isolation trench may be damaged due to a stress generated when bonding the ball portion of the wire to the electrode pad.

On the other hand, as a part of efforts to improve a performance of a semiconductor device, from the perspective of reducing the planar size of the semiconductor device, it is preferable to form the element at the position, which is overlapping with the electrode pad composing the semiconductor device, of the semiconductor substrate composing the semiconductor device as well.

A semiconductor device according to one embodiment includes an electrode pad. Here, in plan view, the electrode pad includes: a first region that contains a center of an exposed portion of the electrode pad; a second region that is located around the first region; and a third region that is located around the first region and that is located between the first region and the second region. Also, a first groove that separates a plurality of semiconductor elements formed in a semiconductor substrate from each other is formed in the semiconductor substrate. Also, the semiconductor substrate includes: a fourth region that overlaps with the third region but not overlaps with each of the first region and the second region, and a fifth region that overlaps with the first region but not overlaps with the third region. Further, the first groove is formed in the semiconductor substrate at the fifth region but not at the fourth region.

According to one embodiment, the performance of the semiconductor device can be improved.

### BRIEF DESCRIPTION OF THE DRAWINGS

FIG. 1 is an upper surface view of a semiconductor device according to one embodiment.

FIG. 2 is a cross-sectional view along a line A-A of FIG. 1.

FIG. 3 is a transparent plan view showing an internal structure of a semiconductor package in a state that a sealing body shown in FIG. 1 is seen through.

FIG. 4 is an enlarged plan view showing one of a plurality of electrode pads of a semiconductor chip shown in FIG. 3.

FIG. 5 is an enlarged plan view showing the electrode pad before bonding a wire shown in FIG. 4.

FIG. 6 is an enlarged cross-sectional view along a line B-B of FIG. 5.

FIG. 7 is an enlarged plan view showing a portion, that overlaps with the enlarged plan view shown in FIG. 5, of a semiconductor substrate shown in FIG. 6.

FIG. 8 is an enlarged plan view schematically showing a positional relationship between a vibration direction of an ultrasonic wave applied during a wire bonding step and DTI.

FIG. 9 is an enlarged plan view showing a first modified example in relation to the semiconductor substrate shown in FIG. 7.

FIG. 10 is an enlarged plan view showing a second modified example in relation to the semiconductor substrate shown in FIG. 7.

FIG. 11 is an enlarged cross-sectional view showing a modified example in relation to an element isolation trench shown in FIG. 6.

FIG. 12 is an enlarged cross-sectional view showing a modified example in relation to a trench formed in the semiconductor substrate shown in FIG. 6.

FIG. 13 is an explanatory view showing an assembly flow of the semiconductor package according to one embodiment.

FIG. 14 is an enlarged plan view showing a state that the semiconductor chip is mounted on a die pad of a lead frame during a semiconductor chip mounting step shown in FIG. 13.

FIG. 15 is an enlarged cross-sectional view showing a detail of a wire bonding step.

FIG. 16 is an enlarged cross-sectional view showing a detail of the wire bond step following FIG. 15.

FIG. 17 is an enlarged plan view showing a modified example in relation to FIG. 4.

FIG. 18 is an enlarged plan view showing a portion, that overlaps with the enlarged plan view shown in FIG. 17, of a semiconductor substrate of a semiconductor chip shown in FIG. 17.

### DETAILED DESCRIPTION

### Description of Forms, Basic Terms and Usage in this Application

In this application, the description of embodiments is divided into multiple sections as necessary for convenience. Unless expressly stated otherwise, these are not independent and separate from each other, regardless of the order of description, and parts of a single example may be details of one another or a part or all of a modified example. In principle, descriptions of similar parts are omitted. Also, each component in an embodiment is not essential, unless expressly stated otherwise, theoretically limited to that number, and obviously otherwise from the context.

Similarly, in the description of the embodiment and the like, regarding materials, compositions, etc., “X consisting of A” or the like does not exclude elements other than A, except when it is clearly indicated that this is not the case and when it is obvious from the context that this is not the case. For example, regarding a component, it means “X including A as a main component” or the like. For example, the term “silicon member” or the like is not limited to pure silicon, and it is needless to say that it also includes a member containing a SiGe (Silicon Germanium) alloy, a multi-element alloy containing silicon as its main component, other additives, or the like. Furthermore, terms like gold plating, Cu layer, nickel plating, etc., unless specifically stated otherwise, are not limited to the pure forms but include members containing gold, Cu, nickel, etc., as their main components.

In addition, reference to a specific numerical value or quantity may be greater than or less than that specific numerical value, unless expressly stated otherwise, theoretically limited to that number, and obviously not so from the context.

In the drawings of the embodiments, the same or similar parts are denoted by the same or similar symbols or reference numerals, and the description will not be repeated in principle.

In addition, in the attached drawings, hatching and the like may be omitted even in a cross-section when it becomes complicated or when it is clearly distinguished from a gap.

In this connection, even if the hole is closed in plan, the outline of the background may be omitted when it is obvious from the description or the like. In addition, hatching or dot patterns may be added to indicate that the region is not a void even if it is not a cross-section or to indicate the boundary of the region.

In this application, a semiconductor device refers to a device that includes a plurality of elements (semiconductor elements) formed on a semiconductor substrate and a wiring layer that electrically connects the plurality of elements. In the following description, a distinction is made between a semiconductor chip and a semiconductor package where the semiconductor chip is mounted on a chip mounting area and is sealed. Each of the semiconductor chip and the semiconductor package is considered as a semiconductor device.

### <Semiconductor Package>

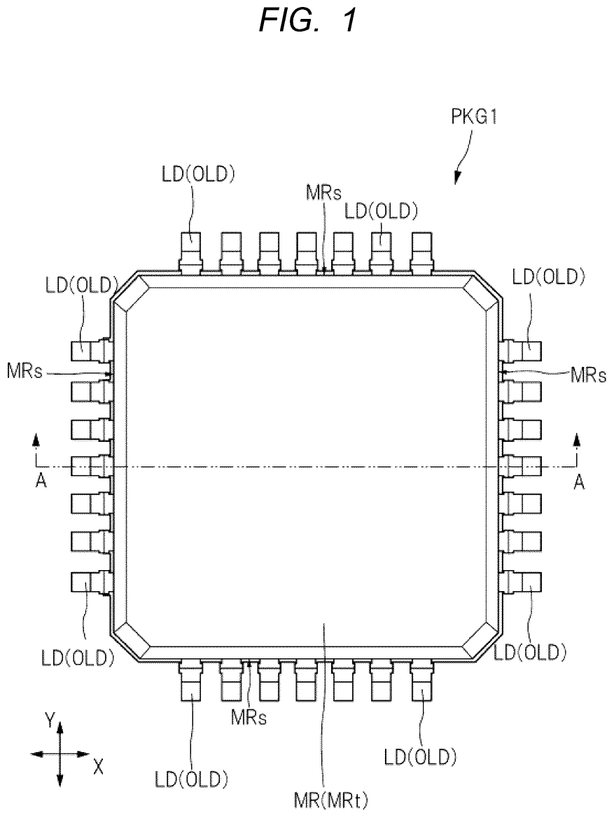

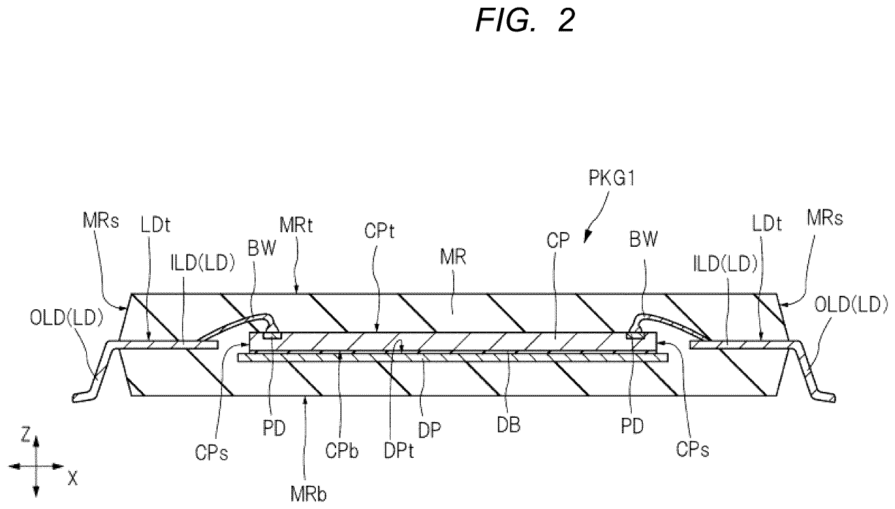

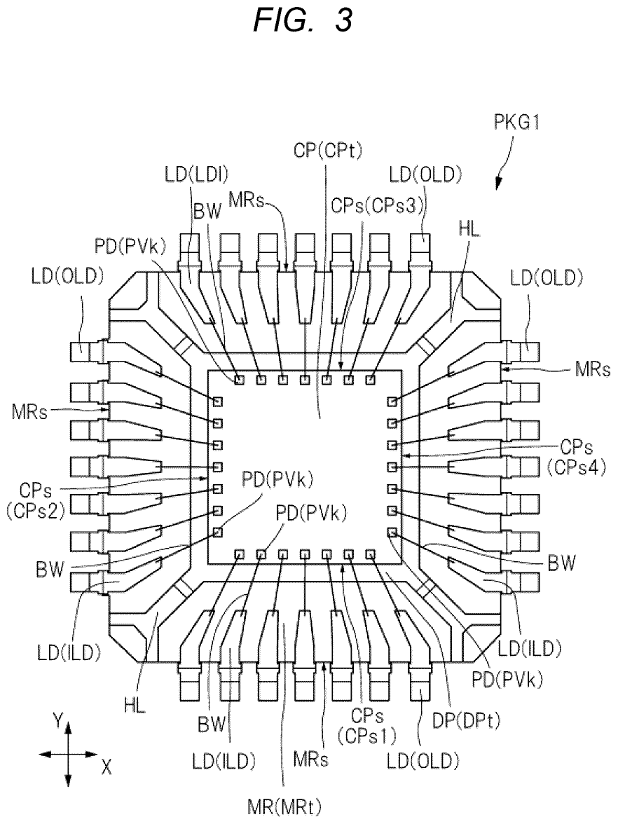

First, an overview of the configuration of the semiconductor package PKG1 in the present embodiment is explained using FIGS. 1 to 3. FIG. 1 is an upper surface view of a semiconductor package according to the present embodiment. Also, FIG. 2 is a cross-sectional view along a line A-A of FIG. 1. Further, FIG. 3 is a transparent plan view showing an internal structure of the semiconductor package in a state that a sealing body shown in FIG. 1 is seen through.

In FIGS. 1 to 3, either the X direction, Y direction (refer to FIGS. 1 and 3), or Z direction (refer to FIG. 2) is described. The Y direction is a side intersecting with the X direction, and in the following description, the X direction and Y direction are orthogonal to each other. The Z direction is orthogonal to both the X direction and the Y direction. In other words, the Z direction is the normal direction to the X-Y plane that includes the X direction and Y direction. In the following description, “thickness” principally means the length in the Z direction. Furthermore, in the following description, “plan view” principally means viewing the X-Y plane.

The technology described in the following embodiment is widely applicable to semiconductor packages where a wire or stud bump (a bump with a ball portion formed at the tip of the wire, the ball portion is bonded to the electrode pad, and then the wire portion is cut) is connected to the electrode pads exposed on the surface of the semiconductor chip. In the present embodiment, as an example of semiconductor packages where wires are connected to the electrode pads of the semiconductor chip, a lead frame type semiconductor package is discussed. In the case of a lead frame type semiconductor package, the semiconductor chip mounted on the die pad of the lead frame and the plurality of leads arranged around the die pad are electrically connected via wires.

As shown in FIGS. 1 to 3, the semiconductor package PKG1 includes a semiconductor chip CP (refer to FIGS. 2 and 3), the plurality of leads (terminals, external terminals) LD arranged around the semiconductor chip CP, and a plurality of wires BW (refer to FIGS. 2 and 3) which are conductive members electrically connecting the semiconductor chip and the plurality of leads LD. Moreover, the semiconductor chip CP and the plurality of wires BW are sealed in a sealing body (resin body) MR. Furthermore, each inner lead portion ILD (refer to FIGS. 2 and 3) of the plurality of leads LD is sealed in the sealing body MR, and each outer lead portion OLD of the plurality of leads LD is exposed from the sealing body MR.

As shown in FIG. 1, the sealing body MR included in the semiconductor package PKG1 has a rectangular planar shape. The sealing body MR includes an upper surface MRt, a lower surface opposite to the upper surface MRt (rear surface, mounted surface) MRb (refer to FIG. 2), and the plurality (four in FIG. 1) of side surfaces MRs located between the upper surface MRt and the lower surface MRb.

Moreover, in the semiconductor package PKG1, the plurality of leads LD is arranged along each of the four side surfaces MRS of the sealing body MR, which has a rectangular planar shape. The plurality of leads LD is made of metal, and in the present embodiment, the plurality of leads LD is a metal member mainly composed of copper (Cu), for example. As in the present embodiment, the semiconductor package in which a plurality of leads LDs is arranged along each of the four sides of the sealing body MR is referred to as QFP (Quad Flat Package). Though not shown, the semiconductor packages in which a plurality of leads LD is arranged along two sides located on opposing sides of four sides of the sealing body MR, and the plurality of leads LD is not arranged on the other two sides, is referred to as SOP (Small Outline Package). This embodiment describes an embodiment applied to a semiconductor package PKG1, which is a QFP, but it may also be applied to a semiconductor package that is an SOP as a modified example.

Furthermore, in the following embodiment, a semiconductor package PKG1, in which the semiconductor chip CP is mounted on a lead frame, is described as representative. However, the technology described below may be applied to semiconductor packages where the semiconductor chip CP is mounted on a wiring substrate not shown in the figures.

As illustrated in FIG. 2, the outer lead portions OLD of the plurality of leads LD project toward the outside of the sealing body MR on the side surface MRs of the sealing body MR. In the case of QFP or SOP, the outer lead portion OLD protrudes from the side surface MRs of the sealing body MR and has a shape curved toward the mounting surface side. Additionally, though not shown, as a modified example for the semiconductor package PKG1, there are semiconductor packages where each of the plurality of leads LD is exposed on the lower surface MRb of the sealing body MR. Semiconductor packages where leads LD are exposed on the lower surface MRb of the sealing body MR include QFN (Quad Flat Non-leaded package) and SON (Small Outline Non-leaded package).

As shown in FIGS. 2 and 3, the semiconductor chip CP is sealed with the sealing body MR. As shown in FIG. 3, the semiconductor chip CP forms a rectangle in plan view, having an upper surface (main surface) CPt, and a lower surface CPb opposite the upper surface CPt (refer to FIG. 2). On the upper surface CPt of the semiconductor chip CP, a plurality of electrode pads (bonding pads) PD is provided along each of the four sides that constitute an outer edge of the upper surface CPt. Furthermore, the semiconductor chip CP (specifically, the semiconductor substrate) is made of, for example, silicon (Si). Although not shown, on the main surface of the semiconductor chip CP (specifically, the semiconductor element forming region provided on the upper surface of the semiconductor substrate of the semiconductor chip CP), a plurality of semiconductor elements (circuit elements) is formed. The plurality of electrode pads PD is electrically connected with the plurality of semiconductor elements, respectively, through wiring (not shown) formed in a wiring layer located inside the semiconductor chip CP (specifically, between the upper surface CPt and the semiconductor element forming region not shown). In other words, the plurality of electrode pads PD is electrically connected with the circuit formed in the semiconductor chip CP.

Moreover, on the upper surface CPt of the semiconductor chip CP, an insulating film covering the substrate and wiring of the semiconductor chip CP is formed, and the surface of each of the plurality of electrode pads PD is exposed in an opening formed in this insulating film. Additionally, these electrode pads PD are made of metal, and in this embodiment, for example, they are made of aluminum (Al).

The semiconductor chip CP is mounted on the die pad DP, which is a chip mounting portion. In the case of semiconductor package PKG1, as shown in FIG. 3, in a plan view, a die pad (chip mounting section) DP, which is a chip mounting section where a semiconductor chip CP is mounted, is arranged between the four sides S1, S2, S3, and S4 of the sealing body MR, and the semiconductor chip CP is mounted on the upper surface (front surface, main surface, chip mounting surface) DPt of the die pad DP. The upper surface DPt of the die pad DP consists of a rectangle whose plane area is larger than the surface area of the semiconductor chip CP. However, the die pad DP is a support member that supports the semiconductor chip CP, and its shape and size can be applied to various modified examples in addition to the example shown in FIG. 3. For example, the planar shape of the die pad DP may be circular. Furthermore, for example, the plane area of the die pad DP may be made smaller than the upper surface CPt of the semiconductor chip CP. In the case of semiconductor package PKG1, the die pad DP is sealed in the sealing body MR. Although not shown, as a modified example for semiconductor package PKG1, there are cases where the lower surface of the die pad DP is exposed from the sealing body MR on the lower surface MRb of the sealing body MR.

Furthermore, as shown in FIG. 2, the semiconductor chip CP is mounted on the die pad DP via a die bond material (adhesive material) DB such that its lower surface CPb faces the upper surface DPt of the die pad DP. In other words, it is mounted by a so-called face-up mounting method, where the opposite surface (lower surface CPb) of the upper surface (main surface) CPton which the plurality of electrode pads PD is formed faces the chip mounting surface (upper surface DPt). This die bond material DB is an adhesive material used when mounting (die bonding) the semiconductor chip CP and, for example, a conductive resin adhesive material containing multiple (numerous) conductive particles (for example, silver particles) in an epoxy-based thermosetting resin, or a solder material.

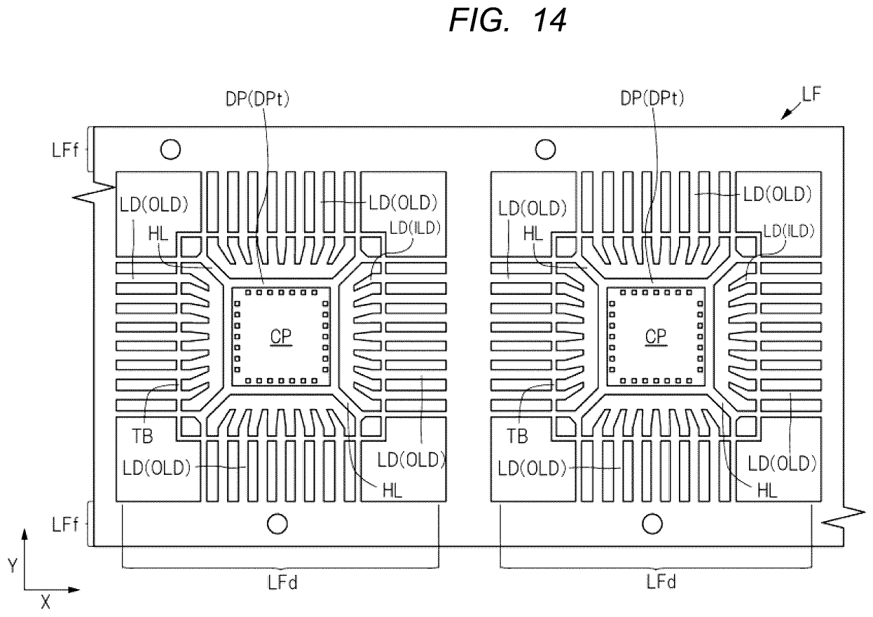

A plurality of leads LD is disposed around the semiconductor chip CP (in other words, around the die pad DP). The plurality of electrode pads (electrodes, pads) PD exposed on the upper surface CPt of the semiconductor chip CP are electrically connected to the inner lead portions ILD of the plurality of leads LD located inside the sealing body MR, via the plurality of wires (conductive members) BW. One end portion of the wire BW (the ball portion BWb shown in FIG. 14 to be described later) is bonded to the electrode pad PD, and the other end portion is bonded to a part of the inner lead portion ILD (wire bonding area).

In the present embodiment, the wire BW is made of copper (Cu), for example. However, the material of the wire BW is not limited to copper and can be applied to various modified examples, such as gold (Au). When the wire BW is made of copper, it is preferable from the viewpoint of reducing material costs or reducing the impedance component of the transmission path formed by the wire.

Furthermore, as shown in FIG. 3, a plurality of suspension leads HL is arranged around the die pad DP. The suspension leads HL are a member for supporting the die pad DP on the support portion (frame portion) of the lead frame during the manufacturing process of the semiconductor package PKG1.

### <Semiconductor Chip>

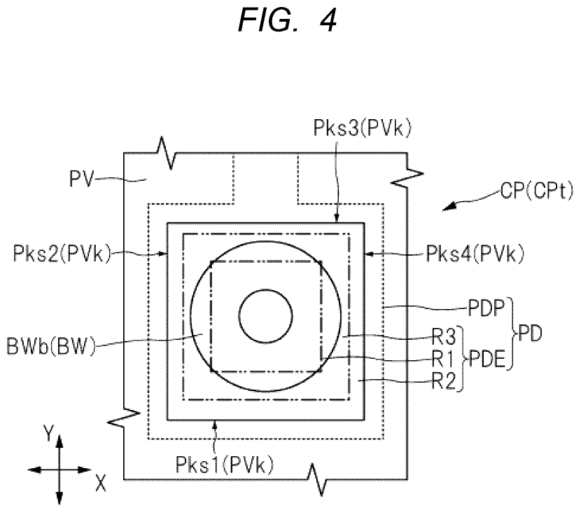

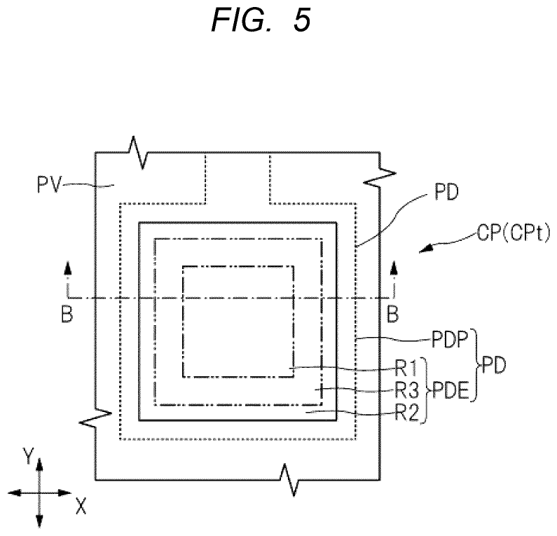

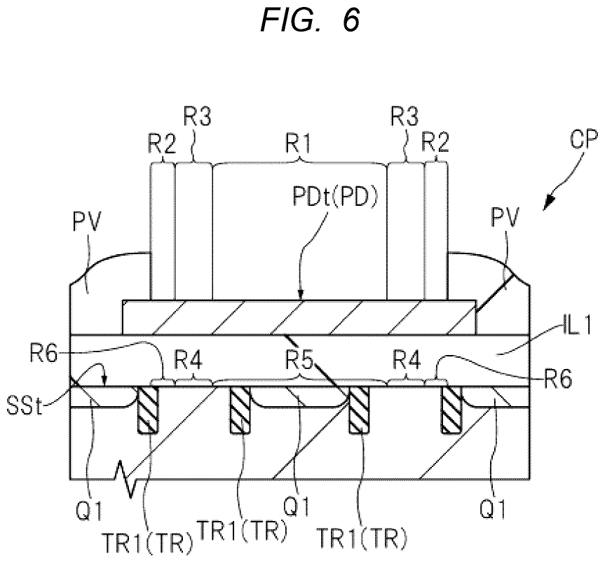

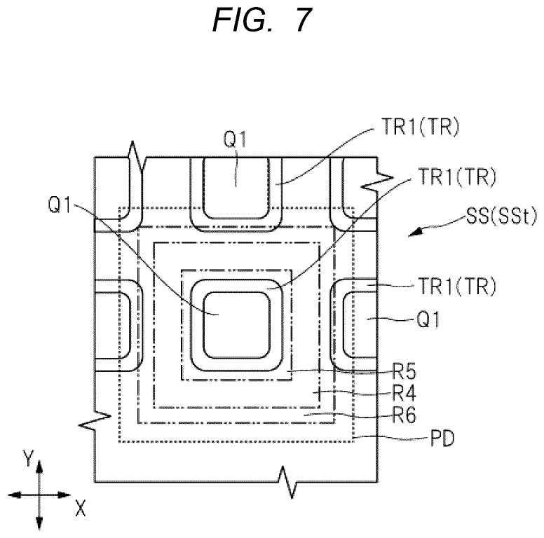

Next, the semiconductor chip shown in FIGS. 2 and 3 will be discussed. FIG. 4 is an enlarged plan view showing one of a plurality of electrode pads of a semiconductor chip shown in FIG. 3. Furthermore, FIG. 5 is an enlarged plan view showing the electrode pad before bonding a wire shown in FIG. 4. In FIGS. 4 and 5, to show the planar shape of the portion of the electrode pad PD covered by the insulating layer PV, the contour of the electrode pad PD is illustrated with a dotted line. In FIGS. 4 and 5, the boundaries of regions R1, R2, and R3 are indicated by a two-dot chain line. FIG. 6 is an enlarged cross-sectional view along a line B-B in FIG. 5. FIG. 7 is an enlarged plan view showing a portion, that overlaps with the enlarged plan shown in FIG. 5, of a semiconductor substrate shown in FIG. 6. In FIG. 7, the boundaries of regions R4, R5, and R6 are indicated by a two-dot chain line. Although FIG. 7 is a plan view of the semiconductor substrate, to show the planar positional relationship between the electrode pad PD and regions R4, R5, and R6 of the semiconductor substrate SS, the contour of the electrode pad PD is illustrated with a dotted line.

In FIG. 6, for simplification, an example is illustrated where a single layer of insulating layer IL1 is placed between the electrode pad PD and the semiconductor substrate SS. However, there may be cases where multiple wiring layers and multiple insulating layers IL1 are alternately stacked between the electrode pad PD and the semiconductor substrate SS.

As shown in FIG. 3, the semiconductor chip CP has an upper surface (main surface) CPt. The upper surface CPt of the semiconductor chip CP forms a square in plan view, comprising a side CPs1 extending in the X direction, a side CPs2 extending along the Y direction that intersects (perpendicular to) with the X direction, a side CPs3 located on the opposite side of the side CPs1, and a side CPs4 located on the opposite side of the side CPs2.

On the upper surface CPt, an insulating layer (protective film, protective insulating film) PV is formed as shown in FIGS. 4 and 6. The insulating layer PV is made of, for example, silicon oxide (SiO2), silicon nitride (SiN), silicon oxynitride (SiON), or a laminated film thereof.

As shown in FIG. 6, the electrode pad PD is formed between the insulating layer PV and the semiconductor substrate SS (specifically, between the insulating layer PV and the insulating layer IL1). A part of the electrode pad PD is exposed from the insulating layer PV at the opening portion PVk formed in the insulating layer PV. A plurality of opening portions PVk (refer to FIG. 3) is formed in the insulating layer PV, and in each of these opening portions PVk, the electrode pad PD is exposed. In other words, the electrode pad PD has an exposed portion PDE that is exposed within the opening portion PVk of the insulating layer PV, and a peripheral portion PDP that is located around the exposed portion PDE and is covered by the insulating layer PV.

As shown in FIG. 4, the ball portion BWb of the wire BW is bonded to a part of the exposed portion PDE of the electrode pad PD. In the present embodiment, the ball portion BWb of the wire BW is bonded to the exposed portion PDE in regions R1 and R3.

The planar shape of the exposed portion PDE of the electrode pad PD forms a rectangle. This can be expressed as follows: Each of the plurality of opening portions PVk formed in the insulating layer PV has a plurality of sides. The opening shape of the opening portion PVk comprises a side Pks1 extending in the X direction, a side Pks2 extending in the Y direction that intersects (perpendicular in the example shown in FIG. 4) the X direction, a side Pks3 located on the opposite side of side Pks1, and a side Pks4 located on the opposite side of side Pks2. The side Pks1 of the opening portion PVk is arranged along the side CPs1 of the semiconductor chip CP, and the side Pks2 of the opening portion PVk is arranged along the side CPs2 of the semiconductor chip CP. Furthermore, the side Pks3 of the opening portion PVk is arranged along the side CPs3 of the semiconductor chip CP, and the side Pks4 of the opening portion PVk is arranged along the side CPs4 of the semiconductor chip CP.

The exposed portion PDE of the electrode pad PD, in a plan view, includes a region R1 containing the center of the opening portion PVk, a region R2 located around the region R1, and a region R3 located around the region R1 and between the region R1 and the region R2.

In a plan view, the region R3 is provided in annular shape along each side of the exposed portion PDE of the electrode pad PD such that a planar shape of the region R3 is formed in hollow square. In the examples shown in FIGS. 4 and 5, the outer edge of region R1 (the boundary between the region R1 and the region R3) and the outer edge of region R3 (the boundary between the region R3 and region the R2) are each square. Moreover, the region R2 is located on the outermost periphery of the exposed portion PDE, and its outer edge (the boundary between region R2 and the surrounding portion PDP) is square.

As shown in FIG. 4, the outer edge of the ball portion BWb of the wire BW, in a plan view, overlaps with the region R3. In the example shown in FIG. 4, part of the outer edge of the ball portion BWb of the wire BW overlaps with the region R3, and another portion of the outer edge of the ball portion BWb of the wire BW overlaps with the region R1.

Furthermore, as shown in FIG. 6, the semiconductor chip CP has a semiconductor substrate SS with an upper surface SSt and an insulating layer IL1 formed on the upper surface SSt of the semiconductor substrate SS. The electrode pad PD is formed on the insulating layer IL1. The insulating layer PV is formed on the insulating layer IL1 so as to cover the peripheral portion PDP of the electrode pad PD.

In FIG. 6, for simplification, an example is shown where a single layer of the insulating layer IL1 is placed between the electrode pad PD and the semiconductor substrate SS. However, the number of layers of the insulating layer IL1 placed between the electrode pad PD and the semiconductor substrate SS is not limited to one layer, and there may be two or more layers. For example, multiple wiring layers not shown may be formed between the electrode pad PD and the semiconductor substrate SS, and multiple insulating layers IL1 may be placed as interlayer insulating films for each wiring layer. The insulating layer IL1 is, for example, made of silicon dioxide (SiO2).

The semiconductor substrate SS is a base material of the semiconductor chip CP and is mainly composed of silicon (Si), for example. The semiconductor device Q1 has a semiconductor region with either p-type or n-type conductivity. The semiconductor region is formed by doping impurities from the upper surface SSt of the semiconductor substrate SS. The bottom surface of the semiconductor device Q1 to be described later is defined as the surface that includes the position farthest from the upper surface SSt in the thickness direction of the semiconductor substrate SS among the doped semiconductor regions.

The plurality of grooves TR is formed on the semiconductor substrate SS. The plurality of grooves TR includes groove TR1. The groove TR1 is a device isolation trench (DTI: Deep Trench Isolation) for separating the plurality of semiconductor devices Q1 formed on the semiconductor substrate SS. Each of the plurality of semiconductor devices Q1 formed on the upper surface SSt of the semiconductor substrate SS includes, for example, a transistor or a diode.

As shown in FIG. 6, based on the upper surface SSt of the semiconductor substrate SS as a reference surface, groove TR1 extends deeper than the semiconductor device Q1. In other words, if the upper surface SSt of the semiconductor substrate SS is taken as the reference surface, the distance from the upper surface SSt to the bottom surface of the groove TR1 is longer than the distance from the upper surface SSt to the bottom surface of the semiconductor element Q1. For instance, in the example shown in FIG. 6, the depth of the groove TR1 (the distance from the upper surface SSt to the bottom surface of the groove TR1) is approximately 1 μm to 20 μm. On the other hand, the depth of the semiconductor element Q1 from the upper surface SSt is approximately 50 nm to 100 nm.

Furthermore, as shown in FIG. 7, the groove TR1 continuously surrounds the semiconductor element Q1. By providing the groove TR1, which is an element isolation trench, around the semiconductor element Q1, it is possible to prevent the plurality of semiconductor elements Q1 from interfering with each other. The width of the groove TR, that is, the dimensions of the opening located on the upper surface SSt of the semiconductor substrate SS as shown in FIG. 6, is approximately 0.5 μm to 1.0 μm, for example. In the following description, the element isolation trench that is arranged to continuously surround the semiconductor element Q1 and extends deeper than the semiconductor element Q1 from the upper surface SSt of the semiconductor substrate SS, used as the reference surface, may be referred to as DTI.

### <Issues Regarding Formation Position of Element Isolation Trench>

Here, according to the studies by the present inventors, it has been found that when DTI is located at a position overlapping with the electrode pad PD, cracks may occur in the insulating layer IL1, leading to detachment from the semiconductor substrate SS. The aforementioned cracks occur during the wire bonding step, where the wire BW is bonded to the electrode pad PD, as shown in FIG. 4. Specifically, it is considered that the stress generated by the ultrasonic waves applied to the ball portion BWb of the wire BW concentrates around the DTI, causing cracks.

The simplest method to prevent the occurrence of the aforementioned cracks is not to place DTI at a position overlapping with the electrode pad PD. In this case, by distancing the electrode pad PD from DTI through which ultrasonic waves propagate, the occurrence of cracks can be prevented.

However, if DTI is not placed at a position overlapping with the electrode pad PD, it becomes impossible to place the semiconductor element Q1 (refer to FIG. 7) at a position overlapping with the electrode pad PD. In this case, the area overlapping with the electrode pad PD cannot be utilized as an active area. Therefore, from the perspective of reducing the planar size of the semiconductor chip CP, it is preferable to place both DTI and the semiconductor element Q1 at positions overlapping with the electrode pad PD.

Therefore, the present inventors have further investigated the conditions under which the aforementioned cracks occur and found that even if DTI is formed at a position overlapping with the electrode pad PD, there are cases where cracks are less likely to occur depending on the positional relationship between the ball portion BWb of the wire BW and DTI. Below, the conditions under which cracks occur and the method of placing DTI considering these conditions will be explained in detail.

As shown in FIG. 4, the ball portion BWb of the wire BW forms a circle in plan view. According to the studies by the present inventors, it has been found that cracks are likely to occur near DTI when DTI is formed at a position overlapping with the outer edge of the ball portion BWb forming a circle. Furthermore, it has been found that DTI positioned at locations not overlapping with the outer edge of the ball portion BWb forming a circle are less likely to cause cracks.

Furthermore, according to the investigations by the present inventors, it has been discovered that the occurrence of cracks is related to the direction of ultrasonic vibrations applied to the wire BW during wire bonding, as well as the extending direction of the DTI, in relation to the frequency of crack occurrence.

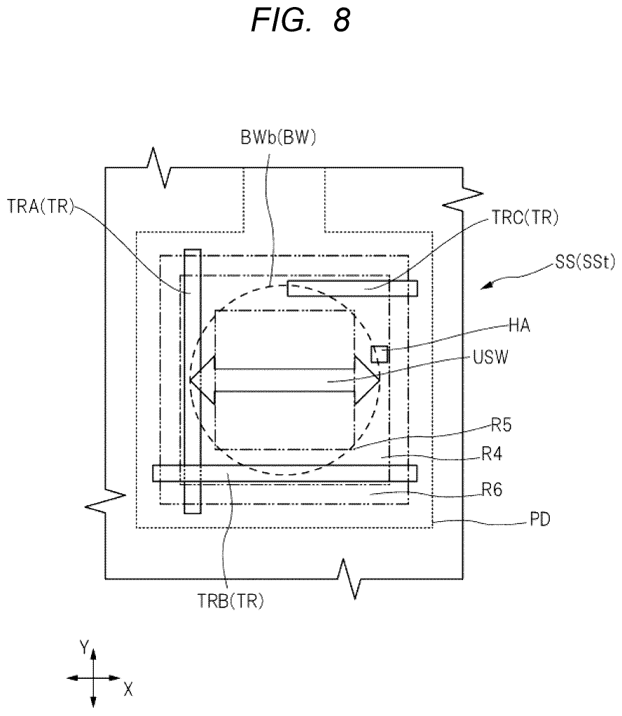

FIG. 8 is an enlarged plan view schematically showing a positional relationship between a vibration direction of an ultrasonic wave applied during a wire bonding step and the DTI. In FIG. 8, the outer edges of the electrode pad PD and the outer edges of the ball portion BWb of the wire BW are indicated by dotted lines. Moreover, in FIG. 8, the boundaries of regions R4, R5, and R6 are indicated by dash-dotted lines.

For example, as shown in FIG. 8, the case where the vibration direction of the ultrasonic wave USW is parallel to the X direction will be explained. The grooves TRA, TRB, and TRC shown in FIG. 8 are grooves of the same depth as the groove TR1 shown in FIGS. 6 and 7.

The groove TRA extends in a direction crossing the vibration direction of the ultrasonic wave USW (in the Y direction in FIG. 8), and a part of groove TRA overlaps with the outer edge of the ball portion BWb. Groove TRA is likely to cause the occurrence of cracks.

The groove TRB extends in the vibration direction of ultrasonic wave USW, and the end of groove TRB does not overlap with the outer edge of the ball portion BWb. In this case, although a part of groove TRB overlaps with the outer edge of the ball portion BWb, groove TRB is unlikely to cause the occurrence of cracks.

The groove TRC extends in the vibrations direction of ultrasonic wave USW, and the end of groove TRC overlaps with the outer edge of the ball portion BWb. Groove TRA is likely to cause the occurrence of cracks.

Moreover, the depth and width (length of one side) of the hole HA shown in FIG. 8 are the same as the depth and width (width of the opening) of the groove TR. The planar shape of hole HA forms a square with sides of approximately the same length as the width of the groove TR (length in the direction crossing the extending direction). Hole HA overlaps with the outer edge of the ball portion BWb. However, hole HA is unlikely to cause the occurrence of cracks.

From the above findings, the mechanism of crack occurrence is presumed as follows: When the DTI is positioned at a location overlapping with the outer edge of the ball portion BWb of the wire BW, the stress generated by the propagation of the ultrasonic wave USW tends to concentrate around the DTI.

However, in cases where the opening area is small, like hole HA, the value of stress propagated around hole HA is small, so it was considered unlikely to cause the occurrence of cracks. Note that in FIG. 8, the case where the opening shape of hole HA is square is exemplified, but the same applies if, for example, the opening diameter of hole HA is circular.

Moreover, in cases like the groove TRB, where it extends along the vibration direction of the ultrasonic wave USW and the end of groove TRB does not overlap with the outer edge of the ball portion BWb, it is considered unlikely for stress to concentrate at the position overlapping with the ball portion BWb, thus making it unlikely to cause the occurrence of cracks.

The vibration direction of the ultrasonic wave USW can be set arbitrarily, but in many cases, the ultrasonic wave USW vibrates in the X direction or the Y direction. In the present embodiment, as shown in FIG. 7, the upper surface SSt of the semiconductor substrate SS includes a region R4, which overlaps with the region R3 (refer to FIG. 5) but not overlaps with each of the region R1 (refer to FIG. 5) and the region R2 (refer to FIG. 5), and a region R5, which overlaps with the region R1 but not overlaps with the region R3. The groove TR1 is formed in the semiconductor substrate SS at the region R5 but not at the region R4.

In other words, in the case of the present embodiment, the region R4, which is likely to overlap with the outer edge of the ball portion BWb of the wire BW (refer to FIG. 4), does not have the groove TR1 placed, and the region R5, which is less likely to overlap with the outer edge of the ball portion BWb of the wire BW (refer to FIG. 4), has the groove TR1 placed.

Furthermore, in the case of the present embodiment, the region R4, which is likely to overlap with the outer edge of the ball portion BWb of the wire BW (refer to FIG. 4), is set as a prohibited area for the placement of the element isolation trench. According to the present embodiment, since the groove TR1 is not placed in the region R4, which is likely to overlap with the outer edge of the ball portion BWb of the wire BW (refer to FIG. 4), it is possible to suppress the occurrence of cracks due to stress concentration regardless of the vibration direction of the ultrasonic wave USW (refer to FIG. 8) in the wire bonding step.

Moreover, according to the present embodiment, on the upper surface SSt of the semiconductor substrate SS, the groove TR1 is placed in the region R5, which is enclosed by the region R4 and overlaps with the electrode pad PD. Therefore, it is possible to form the semiconductor element Q1 in the region R1. Thus, by having the region overlapping with the electrode pad PD become an active area where the semiconductor element Q1 can be formed, it is possible to reduce the planar size of the semiconductor chip CP (refer to FIG. 3).

### <First Modified Example>

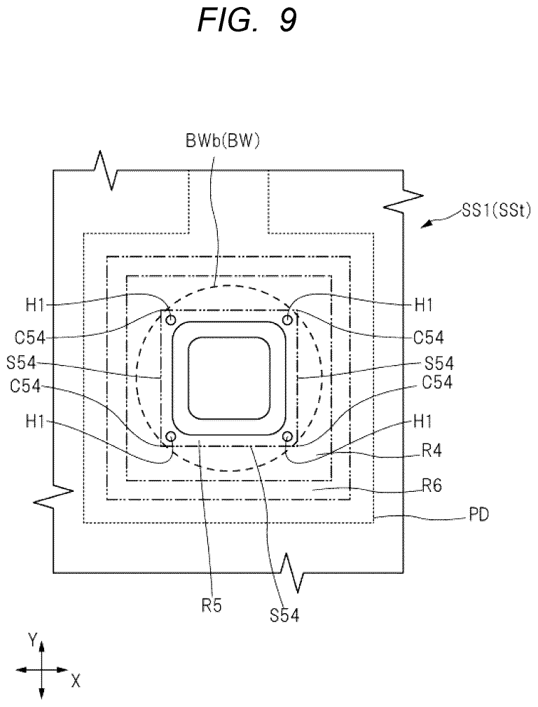

Next, a modified example for the embodiment shown in FIG. 7 will be described. FIG. 9 is an enlarged plan view showing a first modified example in relation to the semiconductor substrate shown in FIG. 7. In FIG. 9, the outer edges of the electrode pad PD and the ball portion BWb of the wire BW are indicated by dotted lines. Also, in FIG. 9, the boundaries of regions R4, R5, and R6 are indicated by dash-dotted lines. The upper surface SSt of the semiconductor substrate SS1 shown in FIG. 9 has regions R4, R5, and R6. This point is similar to the upper surface SSt of the semiconductor substrate SS shown in FIG. 7. Furthermore, as shown in FIG. 9, the planar shape of region R4 is a hollow square. In other words, in plan view, the outer edge (the boundary between region R4 and R6) of region R4 is square, and region R4 is arranged to continuously surround region R5. This point is also similar to the upper surface SSt of the semiconductor substrate SS shown in FIG. 7. Moreover, in plan view, the boundary of region R4 and the boundary of region R5 have four sides S54 and four corners C54 where any two of the four sides S54 intersect. This point is also similar to the upper surface SSt of the semiconductor substrate SS shown in FIG. 7.

The upper surface SSt of the semiconductor substrate SS1 shown in FIG. 9 differs from the upper surface SSt of the semiconductor substrate SS shown in FIG. 7, in the following point. Namely, on the upper surface SSt of the semiconductor substrate SS1, a hole H1 having a smaller opening area than an opening area of the groove TR1 is arranged between each of the four corners C54 and the groove TR1. In the example shown in FIG. 9, four holes Hl are formed in the semiconductor substrate SS at the region R5.

As explained using FIG. 8, even if a hole HA having a smaller opening area is formed at a position overlapping with the outer edge of the ball portion BWb of the wire BW, it is unlikely to cause crack formation. Similarly, each of the plurality of holes H1 shown in FIG. 9 related to this modified example, regardless of the depth of hole H1, is unlikely to cause crack formation. The diameter of hole H1 is the same dimension as one side of hole HA, for example, about 0.5 μm to 1.0 μm. Note that the planar shape of hole Hl is not limited to a circular shape but may also be square, linear, or L-shaped. However, when the hole is square, linear, or L-shaped, the width of the hole is the same dimension as the diameter of hole H1 shown in FIG. 9. Here, the width of the hole refers to the length in the direction crossing the direction in which the hole extends in plan view.

Considering the machining accuracy in the step of bonding the wire BW to the electrode pad PD, the actual bonding location of wire BW may have an error in either or both the X and Y directions from the designed bonding position. Therefore, around the four corners C54 of the boundary between regions R4 and R5, there is a possibility of overlapping with the ball portion BWb depending on the degree of misalignment of wire BW.

In the case of this modified example, near each of the four corners C54 of region R5, which has a square planar shape, there are holes H1 that are unlikely to cause crack formation. Each of the plurality of holes H1 is spaced apart from the groove TR1, which is DTI. Therefore, it is possible to avoid placing the groove TR1 around the four corners C54. In other words, each of the four holes H1 functions as a dummy groove to prevent the groove TR1 from being placed at a position overlapping the outer edge of the ball portion BWb.

The semiconductor substrate SSI shown in FIG. 9 is, except for the differences mentioned above, similar to the semiconductor substrate SS described using FIG. 7. Therefore, duplicate descriptions are omitted.

### <Second Modified Example>

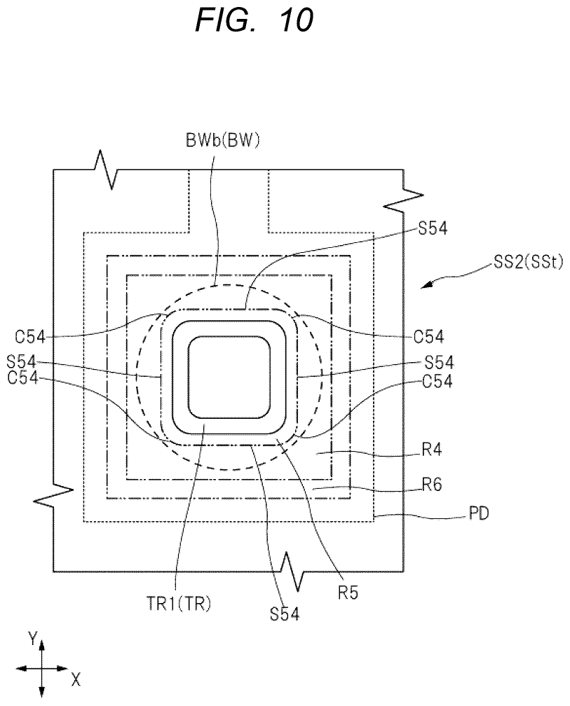

Next, another modified example for the embodiment shown in FIG. 7 will be described. FIG. 10 is an enlarged plan view showing a second modified example in relation to the semiconductor substrate shown in FIG. 7. In FIG. 10, the outer edges of the electrode pad PD and the ball portion BWb of the wire BW are indicated by dotted lines. Also, in FIG. 10, the boundaries of regions R4, R5, and R6 are shown with dashed lines. The upper surface SSt of the semiconductor substrate SS2 shown in FIG. 10 has regions R4, R5, and R6. This point is similar to the upper surface SSt of the semiconductor substrate SS shown in FIG. 7. Moreover, as shown in FIG. 10, the planar shape of region R4 is a hollow square. In other words, in plan view, the outer edge (the boundary between region R4 and R6) of region R4 is square, and region R4 is arranged to continuously surround region R5. This point is also similar to the upper surface SSt of the semiconductor substrate SS shown in FIG. 7. Furthermore, in plan view, the boundary of region R4 and the boundary of region R5 have four sides S54 and four corners C54 where any two of the four sides S54 intersect. This point is also similar to the upper surface SSt of the semiconductor substrate SS shown in FIG. 7.

The upper surface SSt of the semiconductor substrate SS2 shown in FIG. 9 differs from the upper surface SSt of the semiconductor substrate SS shown in FIG. 7, in the following point. Namely, in plan view, each of the four corners C54 has an arc shape.

As mentioned above, considering the machining accuracy in the step of bonding the wire BW to electrode pad PD, the actual bonding location of the wire BW may deviate from the designed bonding position in at least one of the X and Y directions, or in both. Therefore, the vicinity of the four corners C54 among the boundaries between regions R4 and R5 may overlap with the ball portion BWb depending on the degree of misalignment of wire BW.

In cases like this modified example, where each of the four corners C54 is arc-shaped in plan view, compared to the example shown in FIG. 9, the margin between the outer edge of the ball portion BWb and the four corners C54 can be widened. This allows for the avoidance of placing the groove TR1 in a position where it overlaps with the outer edge of the ball portion BWb.

The semiconductor substrate SS2 shown in FIG. 10 is, except for the differences mentioned above, similar to the semiconductor substrate SS described using FIG. 7. Therefore, duplicate descriptions are omitted.

### <Third Modified Example>

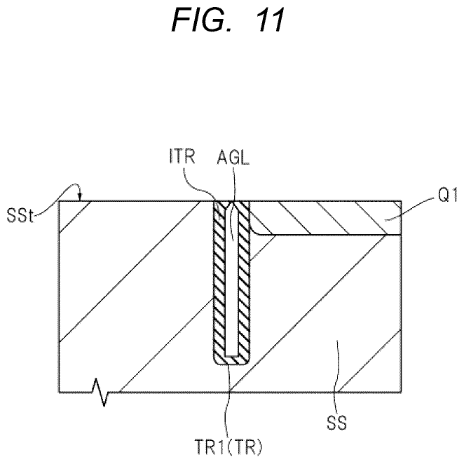

Next, a modified example of the DTI structure will be described. FIG. 11 is an enlarged cross-sectional view showing a modified example in relation to an element isolation trench shown in FIG. 6. In the example shown in FIG. 11, the structure of the groove TR1, which is DTI, differs from the example shown in FIG. 7, in the following point. Namely, inside the groove TR1 shown in FIG. 11, there is an insulating material layer ITR covering the inner wall of the groove TR1, and an air layer AGL surrounded by the insulating material layer ITR. The groove TR1 containing the air layer AGL shown in FIG. 11 has the following advantage compared to the groove TR1 without the air layer AGL: Namely, the pressure resistance characteristic (voltage resistance characteristic) of the semiconductor integrated circuit is improved. For example, if the voltage resistance value of the groove TR1 shown in FIG. 7 is 75 V (volts), the voltage resistance value when using the groove TR1 shown in FIG. 11 is 100 V (volts).

On the other hand, according to the studies conducted by the inventors of the present invention, it has been found that the frequency of crack occurrence significantly increases when the groove TR1, which includes an air layer AGL, is formed in a position overlapping the ball portion BWb of the wire BW (refer to FIG. 8).

However, as mentioned above, if the groove TR1 shown in FIG. 11 is not located in the region R4, it is possible to suppress the frequency of crack occurrence.

Thus, according to this modified example, it is possible to improve the pressure resistance characteristics of the semiconductor integrated circuit while suppressing the occurrence of cracks.

### <Fourth Modified Example>

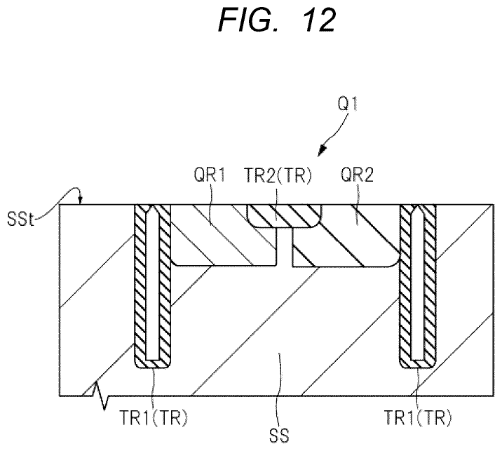

Next, a modified example of the groove formed in the semiconductor substrate will be described. FIG. 12 is an enlarged cross-sectional view showing a modified example of the groove formed in the semiconductor substrate shown in FIG. 6.

The semiconductor element Q1 may be formed by a combination of the plurality of semiconductor regions. For example, in the case shown in FIG. 12, the semiconductor element Q1 has semiconductor regions QR1 and QR2. There are various modified examples of the configurations of semiconductor regions QR1 and QR2, for instance, one of semiconductor regions QR1 and QR2 is an n-type semiconductor region, and the other is a p-type semiconductor region. A groove TR2 is formed between semiconductor regions QR1 and QR2. In the case of the modified example shown in FIG. 12, the plurality of grooves TR formed on the upper surface SSt of the semiconductor substrate SS includes groove TR1, among others, and groove TR2.

The groove TR2 is one of the plurality of grooves TR formed on the upper surface SSt of the semiconductor substrate SS. The groove TR2 is a groove known as STI (Shallow Trench Isolation). The groove TR2 is positioned across two different semiconductor regions and serves as an insulating area to prevent leakage current between adjacent semiconductor regions.

Taking the upper surface SSt of the semiconductor substrate SS as the reference surface, the groove TR2 is shallower than the groove TR1. In the example shown in FIG. 12, the depth of the groove TR2 (the distance from the upper surface SSt to the bottom surface of the groove TR2) is about 30 nm. In such a shallow groove TR2, it is less likely to cause the aforementioned cracks. Therefore, even if the groove TR2 is located in the region R4 shown in FIG. 7, and the outer edge of the ball portion BWb of the wire BW shown in FIG. 4 overlaps with the groove TR2 shown in FIG. 12, the frequency of crack occurrence does not increase.

### <Method of Manufacturing Semiconductor Package>

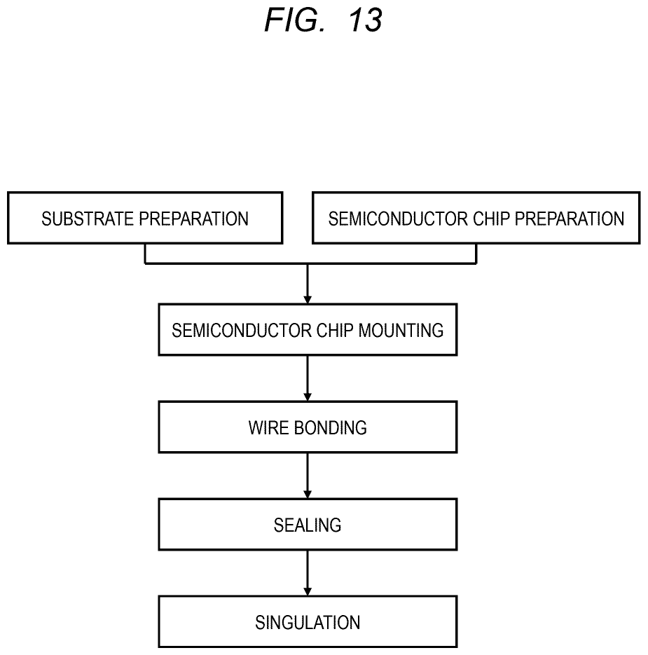

Next, the manufacturing method of the semiconductor package PKG1 shown in FIG. 1 will be described. The semiconductor package PKG1 of the present embodiment is manufactured according to the assembly flow shown in FIG. 13. FIG. 13 is an explanatory diagram showing the assembly flow of the semiconductor package of the present embodiment. In the example shown in FIG. 13, the manufacturing method of the semiconductor package of the present embodiment includes a semiconductor chip preparation step, a substrate preparation step, a semiconductor chip mounting process, a wire bonding step, a sealing step, and a singulation step. In the following description, when explaining each component composing the semiconductor package, FIGS. 1 to 12 will be referenced as necessary.

### <Substrate Preparation Step>

In the substrate preparation step shown in FIG. 13, a lead frame (substrate) LF shown in FIG. 14 is prepared. FIG. 14 is an enlarged plan view showing the state where the semiconductor chip is mounted on the die pad of the lead frame in the semiconductor chip mounting step shown in FIG. 13. As a modified example for the present embodiment, in the case of a manufacturing method of a semiconductor package where the semiconductor chip CP is mounted on a wiring substrate not shown, a wiring substrate is prepared instead of the lead frame in this step.

As shown in FIG. 14, the lead frame LF prepared in this step includes the plurality of device forming sections LFd connected to the frame section (frame portion) LFf. Each of the plurality of device forming sections LFd corresponds to one semiconductor package PKG1 shown in FIG. 1. The lead frame LF is a so-called multi-unit substrate in which a plurality of device forming sections LFd is arranged.

The lead frame LF is made of a metal material mainly composed of copper (Cu). Each of the plurality of device forming sections LFd is connected to the frame section LFf. The frame section LFf serves as a support portion that supports each component formed within the device forming section LFd until the lead separation step shown in FIG. 13.

Furthermore, in the device forming section LFd, a die pad DP and a plurality of leads LD are formed as shown in FIG. 3. The die pad DP is connected to the frame section LFf through a suspension lead and supported by the frame section LFf. Each of the plurality of leads LD is connected to the frame section LFf through a tie bar TB and supported by the frame section LFf.

### <Semiconductor Chip Preparation Step>

In the semiconductor chip preparation step shown in FIG. 13, the semiconductor chip CP shown in FIG. 14 is prepared. The semiconductor chip CP prepared in this step is, as shown in FIG. 14, a semiconductor chip before the wire BW (refer to FIG. 3) is bonded. Since the detailed structure of the semiconductor chip CP has already been explained using FIGS. 2 to 12, redundant explanations are omitted.

### <Semiconductor Chip Mounting Step>

Next, in the semiconductor chip mounting step shown in FIG. 13, the semiconductor chip CP is mounted on the die pad DP as shown in FIG. 14.

In this step, as shown in FIG. 2, the semiconductor chip CP is mounted on the upper surface DPt of the die pad DP via a die bond material DB. In this step, after applying the die bond material DB on the upper surface DPt of the die pad DP, the semiconductor chip CP is placed on the die bond material DB. Then, by curing the die bond material DB, the semiconductor chip CP and the die pad DP are fixed.

In this step, as shown in FIG. 2, the semiconductor chip CP is mounted on the die pad DP in a state where the lower surface CPb of the semiconductor chip CP faces the upper surface DPt of the die pad DP. This allows for the easy joining of wires BW (refer to FIG. 2) to each of the plurality of electrode pads PD located on the upper surface CPt of the semiconductor chip in the subsequent wire bonding step.

### <Wire Bonding Step>

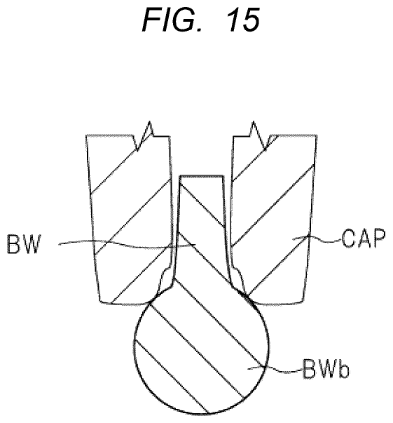

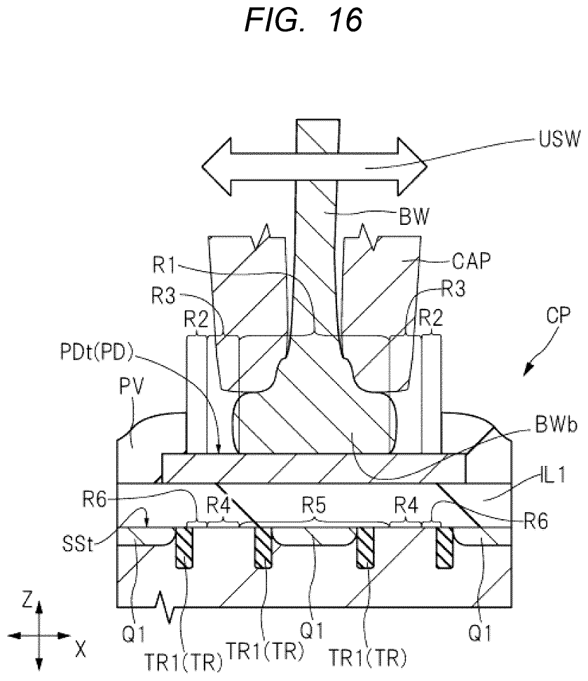

Next, in the wire bonding step shown in FIG. 13, the wire is bonded to the electrode pads PD of the semiconductor chip CP as shown in FIG. 3. In the present embodiment, during the wire bonding step, the electrode pads PD of the semiconductor chip CP and the leads LD are electrically connected via the wire BW. FIGS. 15 and 16 are an enlarged cross-sectional view showing a detail of the wire bonding step.

The following describes the method of bonding the wire BW to the electrode pads PD using the ball bonding method, with reference to FIGS. 15 and 16. When bonding the ball portion BWb of the wire BW to the electrode pad PD as shown in FIG. 4 using the ball bonding method, the bonding strength can be improved by applying high-frequency vibrations such as an ultrasonic wave vibration to the ball portion BWb. “Ultrasonic wave” refers to elastic waves with frequencies higher than the human audible range. In this application, high frequencies of 20 kHz or more are referred to as “ultrasonic wave”.

In the ball bonding step, in addition to the application of ultrasonic, a scrubbing action that removes the oxide film on the joining surface between the electrode pad PD and the ball portion BWb may be performed. The vibration direction of the ultrasonic wave USW explained using FIG. 8 refers to the vibration direction of the ultrasonic applied in the wire bonding step, which is distinguished from the vibration direction of the scrubbing action.

In the wire bonding step, first, as shown in FIG. 15, the tip of the wire BW held by the capillary CAP is heated and melted to form the ball portion BWb.

Next, as shown in FIG. 16, the capillary CAP holding the wire BW is moved towards the electrode pad PD, pressing the ball portion BWb onto the upper surface PDt of the electrode pad PD. At this time, the ultrasonic wave USW is applied through the wire BW. In the example shown in FIG. 16, the ultrasonic wave USW is vibrating in the X direction. Note that in the example shown in FIG. 16, although the vibration direction of the ultrasonic wave USW is along the X direction, as a modified example, there may be cases where the vibration direction of the ultrasonic wave USW is in the Y direction as shown in FIG. 7.

In this step, as shown in FIG. 4, the wire BW is bonded in a position where the outer edge of the ball portion BWb overlaps with the region R3 in a plan view. As shown in FIGS. 6 and 16, on the upper surface SSt of the semiconductor substrate SS, the region R4 overlaps with the region R3. Specifically, as can be understood by comparing FIGS. 4 and 5, the entirety of the region R4 overlaps with the region R3. Therefore, in this step, in a plan view, the wire BW is bonded in a position where the outer edge of the ball portion BWb overlaps with the region R4.

Here, as already explained, the region R4 does not have the groove TR1 formed in it, which could cause cracking. Although groove TR1 is formed in the region R5, the groove TR1 formed in the region R5 is less likely to be a cause of cracking. As a result, according to the manufacturing method of the semiconductor package of the present embodiment, even if a groove TR1, which is DTI, is formed at a position overlapping the electrode pad PD, it is possible to reduce the frequency of crack occurrence.

Next, the holding state of the wire BW by the capillary CAP shown in FIG. 16 is released, and the capillary CAP is moved upward. At this time, since the ball portion BWb is bonded to the electrode pad PD, a wire BW with the ball portion BWb bonded to the electrode pad PD is obtained.

Next, after moving the capillary CAP to the wire bonding area of the lead LD shown in FIG. 3, the wire BW is bonded to the lead LD. Then, by cutting the excess wire, a wire BW as shown in FIGS. 2 and 3 is obtained.

As a modified example of the present embodiment, there may be cases where a stud bump is bonded to the electrode pad PD. In this case, after the step explained using FIG. 16, the wire BW is cut at the top of the ball portion BWb. As a result, the ball portion BWb remains on the electrode pad PD, and this ball portion BWb can be used as a stud bump.

### <Sealing Step>

Next, in the sealing step shown in FIG. 13, the semiconductor chip CP, the die pad DP, the plurality of leads LD (each inner lead portion ILD), and the plurality of wires BW shown in FIG. 2 are sealed with an insulating resin, thereby forming the sealed body MR as shown in FIGS. 1 and 2. In this step, for example, a molding die including an upper mold (first mold) and a lower mold (second mold) is used to form the sealed body MR by the so-called transfer mold method. The lead frame LF, including the die pad DP and the plurality of leads LD of the device forming sections LFd shown in FIG. 14, is positioned within the cavity of the molding die. Then, the lead frame LF is clamped between the upper mold and the lower mold. In this state, when a softened (plasticized) thermosetting resin (insulating resin) is pressed into the cavity of the molding die, the insulating resin is molded following the shape of the cavity.

At this time, a part of each of the plurality of leads LD (outer lead portion OLD) is in contact with the molding die. Therefore, as shown in FIG. 2, after this step, the outer lead portions OLD of the plurality of leads LD are exposed from the sealed body MR.

After the sealed body MR is formed, a part of the thermosetting resin contained in the sealed body MR is heated until it hardens (referred to as provisional hardening). Once it becomes possible to remove the lead frame LF from the molding die due to this provisional hardening, the lead frame LF is removed from the molding die. Then, it is transported to a heating furnace for further heat treatment (cure bake). As a result, the remaining thermosetting resin hardens, and the sealed body MR is obtained.

### <Singulation Step>

Next, in the singulation step shown in FIG. 13, the structures formed within the device forming sections LFd are separated and individualized. In this step, the tie bar TB and the tips of the outer lead portions OLD of the plurality of leads LD shown in FIG. 14 are cut. Also, in this step, the shape of the outer lead portion OLD is formed as shown in FIG. 2. As a result, the semiconductor package PKG1 shown in FIGS. 1 to 3 is obtained.

In the manufacturing method of the semiconductor package described using FIGS. 13 to 16, it is possible to apply any one or any combination of the first through fourth modified examples that have already been explained.

### <Modified Example of Manufacturing Method>

Next, a modified example of the method of manufacturing the semiconductor device described using FIGS. 13 to 16 will be explained. The modified examples described below, except for the predetermined direction of ultrasonic vibration and the different division of areas in the exposed portion of the electrode pad, are similar to the manufacturing method of the semiconductor package described using FIGS. 13 to 16. Therefore, the differences from the aforementioned manufacturing method will be explained below.

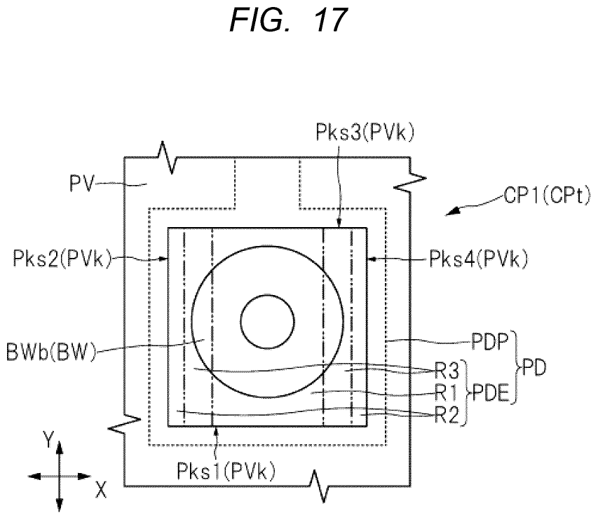

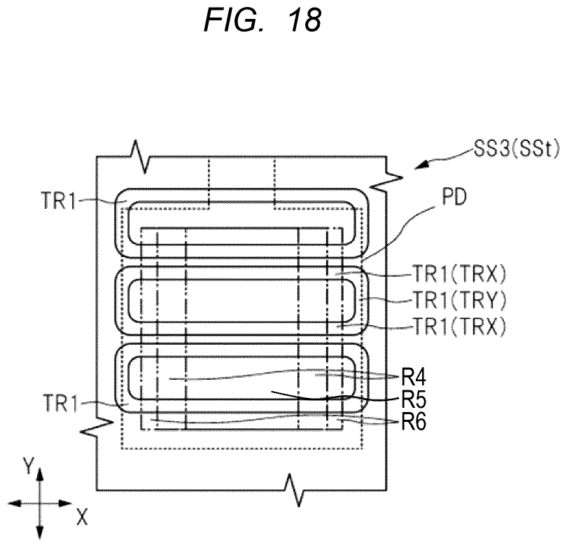

FIG. 17 is an enlarged plan view showing a modified example in relation to FIG. 4. FIG. 18 is an enlarged plan view showing a portion, that overlaps with the enlarged plan shown in FIG. 17, of a semiconductor substrate of a semiconductor chip shown in FIG. 17. In FIG. 17, the boundaries of the regions R1, R2, and R3 are indicated by dashed lines. In FIG. 18, the boundaries of regions R4, R5, and R6 are indicated by dashed lines. Although FIG. 18 is a plan view of the semiconductor substrate, the contour of the electrode pad PD is illustrated with a dotted line.

The semiconductor chip CP1 shown in FIG. 17 differs from the semiconductor chip CP shown in FIG. 4, in the following point.

First, as shown in FIG. 17, the exposed portion PDE of the electrode pad PD, in plan view, includes a region R1 that contains a center of the opening portion PVk, a region R2 that is located outside the region R1, and a plurality of regions R3 (two in FIG. 17) that is located on both sides of the region R1 and that is located between the region R1 and the region R2. The planar shape of the exposed portion of the electrode pad PD is square, similar to the semiconductor chip CP shown in FIG. 4.

Each of the plurality of regions R3 is provided in a band (strip) shape along the sides of the exposed portion of the electrode pad PD that extend in the Y direction (sides Pks2 and Pks4) in plan view.

Furthermore, as shown in FIG. 18, the upper surface SSt of the semiconductor substrate SS3 includes a plurality of regions R4 that overlaps with any of the plurality of regions R3 but not overlaps with each of the region R1 and the region R2, and the region R5 that overlaps with either the region R1 or the region R2 but not overlaps with the plurality of regions R3.

The groove TR1 formed on the upper surface SSt of the semiconductor substrate SS3 includes at least one of a groove TRY, which is extending in the Y direction, and a groove TRX, which is extending in the X direction intersecting with the Y direction. In the example shown in FIG. 18, the groove TR1 includes both the grooves TRY and TRX. The one of the groove TRY and the grove TRX is formed in the semiconductor substrate SS3 at the region R5. In the example shown in FIG. 17, the groove TRX is formed in the semiconductor substrate SS3 at the region R5.

The groove TRY is not formed in the semiconductor substrate SS3 at each of the plurality of regions R4, and the end portion of the groove TRX is not formed in the semiconductor substrate SS3 at each of the plurality of regions R4. Here, the end portion of the groove TRX refers to the portion where the extending direction of the groove TRX changes. In the example shown in FIG. 18, the groove TR1 has an endless shape. However, the grooves TRX and TRY each forming the groove TR1 intersect with each other. Each of the four intersections where the groove TRX and the groove TRY intersect with each other is the end portion of the groove TRX and also the end portion of the groove TRY. In the wire bonding step of the manufacturing method for the semiconductor package of this modified example, the ultrasonic wave USW that vibrates in the X direction is applied while the ball portion formed at the tip of the wire is in contact with the electrode pad PD, similar to the example described using FIG. 16.

As already explained using FIG. 8, the groove TRB extends in the vibration direction of the ultrasonic wave USW, and the end portion of the groove TRB does not overlap with the outer edge of the ball portion BWb. In this case, although a part of the groove TRB overlaps with the outer edge of the ball portion BWb, the groove TRB is unlikely to cause cracking.

From this finding, when the vibration direction of the ultrasonic wave USW can be defined, it is possible to reduce the area of the region R4 (refer to FIG. 18), which is a prohibited area for DTI placement. In other words, it is possible to expand the area where DTI can be placed. As a result, for the semiconductor substrate SS3, it is possible to improve the area ratio of the active region on the upper surface SSt compared to the semiconductor substrate SS shown in FIG. 7.

In the case of this modified example, as shown in FIG. 18, grooves TR1 are placed at a higher density compared to the example shown in FIG. 7. However, since the conditions that increase the frequency of crack occurrence are avoided, it is possible to suppress the occurrence of cracks.

In the case of this modified example, each of the plurality of grooves TR1 includes grooves TRX and TRY, but the length of groove TRX is longer than that of groove TRY.

In the cases of FIGS. 17 and 18, it was explained that the ultrasonic wave USW that vibrate in the X direction are applied, similar to the example shown in FIG. 16. However, as a modified example, there may be cases where the ultrasonic wave USW that vibrates in the Y direction is applied.

Although not shown, in the modified example where the vibration direction of the ultrasonic wave USW is along the Y direction, each of the regions R1, R2, and R3 shown in FIG. 17 is arranged in a band extending in the X direction. Similarly, each of the regions R4, R5, and R6 shown in FIG. 18 is arranged in a band extending in the X direction. Furthermore, in each of the plurality of regions R4, no groove TRX is formed, and the end portion of the groove TRY is not formed.

The invention made by the present inventor has been described above in detail based on the embodiment, but the present invention is not limited to the embodiment described above, and it is needless to say that various modifications can be made without departing from the gist thereof.

What is claimed is:

1. A semiconductor device comprising:
a semiconductor substrate having a first surface;
a first insulating layer formed on the first surface of the semiconductor substrate;
an electrode pad formed on the first insulating layer;
a second insulating layer formed on the first insulating layer so as to cover a peripheral portion of the electrode pad; and
a plurality of grooves formed in the semiconductor substrate,
wherein the electrode pad includes:
an exposed portion that is exposed within an opening portion of the second insulating layer; and
the peripheral portion that is located around the exposed portion and that is covered by the second insulating layer,
wherein, in plan view, the exposed portion of the electrode pad includes:
a first region that contains a center of the opening portion;
a second region that is located around the first region; and
a third region that is located around the first region and that is located between the first region and the second region,
wherein a planar shape of the exposed portion of the electrode pad is square,
wherein, in plan view, the third region is provided in annular shape along each side of the exposed portion of the electrode pad such that a planar shape of the third region is formed in hollow square,
wherein the plurality of grooves includes a first groove that separates a plurality of semiconductor elements formed in the semiconductor substrate from each other,
wherein the semiconductor substrate includes:
a fourth region that overlaps with the third region but not overlaps with each of the first region and the second region, and
a fifth region that overlaps with the first region but not overlaps with the third region, and
wherein the first groove is formed in the semiconductor substrate at the fifth region but not at the fourth region.

2. The semiconductor device according to claim 1, wherein taking the first surface of the semiconductor substrate as a reference surface, the first groove extends to a deeper position than each of the plurality of semiconductor elements.

3. The semiconductor device according to claim 2,
wherein, in plan view, a boundary between the fourth region and the fifth region has four sides and four corners where any two of the four sides intersect with each other, and
wherein, on the first surface of the semiconductor substrate, a hole having a smaller opening area than an opening area of the first groove is arranged between each of the four corners and the first groove.

4. The semiconductor device according to claim 2,
wherein, in plan view, a boundary between the fourth region and the fifth region has four sides and four corners where any two of the four sides intersect with each other, and
wherein, in plan view, each of the four corners has an arc shape.

5. The semiconductor device according to claim 2, wherein, within the first groove, there is an insulating material layer covering the inner wall of the first groove and an air layer surrounded by the insulating material layer.

6. The semiconductor device according to claim 2, wherein, taking the first surface of the semiconductor substrate as the reference surface, the plurality of grooves includes a second groove that is shallower than the first groove.

7. The semiconductor device according to claim 2,
wherein a wire having a ball portion is bonded to the exposed portion of the electrode pad, and
wherein, in a plan view, an outer edge of the ball portion of the wire overlaps with each of the third region and fourth region.

8. A method of manufacturing a semiconductor device, comprising:
(a) preparing a semiconductor chip having an electrode pad; and
(b) bonding a wire to the electrode pad of the semiconductor chip,
wherein the semiconductor chip includes:
a semiconductor substrate having a first surface;
a first insulating layer formed on the first surface of the semiconductor substrate;
an electrode pad formed on the first insulating layer;
a second insulating layer formed on the first insulating layer so as to cover a peripheral portion of the electrode pad; and
a plurality of grooves formed in the semiconductor substrate,
wherein the electrode pad includes:
an exposed portion that is exposed within an opening portion of the second insulating layer; and
the peripheral portion that is located around the exposed portion and that is covered by the second insulating layer,
wherein, in plan view, the exposed portion of the electrode pad includes:
a first region that contains a center of the opening portion;
a second region that is located around the first region; and
a third region that is located around the first region and that is located between the first region and the second region,
wherein a planar shape of the exposed portion of the electrode pad is square,
wherein, in plan view, the third region is provided in annular shape along each side of the exposed portion of the electrode pad such that a planar shape of the third region is formed in hollow square,
wherein the plurality of grooves includes a first groove that separates a plurality of semiconductor elements formed in the semiconductor substrate from each other,
wherein the semiconductor substrate includes:
a fourth region that overlaps with the third region but not overlaps with each of the first region and the second region, and
a fifth region that overlaps with the first region but not overlaps with the third region,
wherein the first groove is formed in the semiconductor substrate at the fifth region but not at the fourth region, and
wherein, in the (b), an ultrasonic wave is applied, while a ball portion formed at a tip of the wire is in contact with the electrode pad.

9. The method according to claim 8, wherein, in the (b), the wire is bonded to the electrode pad such that an outer edge of the ball portion overlaps with each of the third region and the fourth region in plan view.

10. The method according to claim 8, wherein taking the first surface of the semiconductor substrate as a reference surface, the first groove extends to a deeper position than each of the plurality of semiconductor elements.

11. The method according to claim 10,
wherein, in plan view, a boundary between the fourth region and the fifth region has four sides and four corners where any two of the four sides intersect with each other, and
wherein, on the first surface of the semiconductor substrate, a hole having a smaller opening area than an opening area of the first groove is arranged between each of the four corners and the first groove.

12. The method according to claim 10,
wherein, in plan view, a boundary between the fourth region and the fifth region has four sides and four corners where any two of the four sides intersect with each other, and
wherein, in plan view, each of the four corners has an arc shape.

13. The method according to claim 10, wherein, within the first groove, there is an insulating material layer covering the inner wall of the first groove and an air layer surrounded by the insulating material layer.

14. The method according to claim 10, wherein, taking the first surface of the semiconductor substrate as the reference surface, the plurality of grooves includes a second groove that is shallower than the first groove.

15. A method of manufacturing a semiconductor device, comprising:
(a) preparing a semiconductor chip having an electrode pad; and
(b) bonding a wire to the electrode pad of the semiconductor chip,
wherein the semiconductor chip includes:
a semiconductor substrate having a first surface;
a first insulating layer formed on the first surface of the semiconductor substrate;
an electrode pad formed on the first insulating layer;
a second insulating layer formed on the first insulating layer so as to cover a peripheral portion of the electrode pad; and
a plurality of grooves formed in the semiconductor substrate,
wherein the electrode pad includes:
an exposed portion that is exposed within an opening portion of the second insulating layer; and
the peripheral portion that is located around the exposed portion and that is covered by the second insulating layer,
wherein, in plan view, the exposed portion of the electrode pad includes:
a first region that contains a center of the opening portion;
a second region that is located outside the first region; and
a plurality of third regions that is located on both sides of the first region and that is located between the first region and the second region,
wherein a planar shape of the exposed portion of the electrode pad is square,
wherein, in plan view, the plurality of third regions is provided in band shape along a side, which is extending in a first direction, among sides of the exposed portion of the electrode pad,
wherein the plurality of grooves includes a first groove that separates a plurality of semiconductor elements formed in the semiconductor substrate from each other,
wherein the semiconductor substrate includes:
a plurality of fourth regions that overlaps with any of the plurality of third regions but not overlaps with each of the first region and the second region, and
a fifth region that overlaps with the first region but not overlaps with the plurality of third regions,
wherein the first groove includes at least one of a first direction groove, which is extending in the first direction, and a second direction groove, which is extending in a second direction intersecting with the first direction,
wherein the one of the first direction groove and the second direction groove is formed in the fifth region, and
wherein, in the (b), an ultrasonic wave is applied in the second direction, while a ball portion formed at a tip of the wire is in contact with the electrode pad.

16. The method according to claim 15, wherein, in the (b), the wire is bonded to the electrode pad such that an outer edge of the ball portion overlaps with each of the plurality of third regions and the plurality of fourth regions in plan view.

17. The method according to claim 16, wherein taking the first surface of the semiconductor substrate as a reference surface, the first groove extends to a deeper position than each of the plurality of semiconductor elements.

18. The method according to claim 16, wherein, within the first groove, there is an insulating material layer covering the inner wall of the first groove and an air layer surrounded by the insulating material layer.

19. The method according to claim 16, wherein, taking the first surface of the semiconductor substrate as the reference surface, the plurality of grooves includes a second groove that is shallower than the first groove.
